(19) United States
(12) Patent Application Publication
(10) Pub. No.: US 2025/0294844 A1
(43) Pub. Date: Sep. 18, 2025

(54) WRAP AROUND METAL CONTACT

(71) Applicant: International Business Machines Corporation, Armonk, NY (US)

(72) Inventors: Tsung-Sheng Kang, Ballston Lake, NY (US); Alexander Reznicek, Troy, NY (US); Ruilong Xie, Niskayuna, NY (US); Koichi Motoyama, Clifton Park, NY (US)

(21) Appl. No.: 18/604,150

(22) Filed: Mar. 13, 2024

(51) Int. Cl. H01L 29/417; H01L 23/528

(52) U.S. Cl. CPC H10D 64/251; H01L 23/5286

(57) ABSTRACT

A semiconductor structure includes a first frontside source/drain region, and a first frontside source/drain metal contact disposed on a top surface and over a portion of each sidewall of the first frontside source/drain region.

### BACKGROUND

Semiconductors and integrated circuit chips have become ubiquitous within many products, particularly as they continue to decrease in cost and size. There is a continued desire to reduce the size of structural features and/or to provide a greater number of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Illustrative embodiments of the present application include techniques for use in semiconductor manufacture. In an illustrative embodiment, a semiconductor structure includes a first frontside source/drain region, and a first frontside source/drain metal contact disposed on a top surface and over a portion of each sidewall of the first frontside source/drain region.

In another illustrative embodiment, a semiconductor structure includes a first frontside source/drain metal contact, and a first frontside source/drain region fully disposed within the first frontside source/drain metal contact.

In yet another illustrative embodiment, an integrated circuit includes one or more semiconductor devices. At least one of the one or more semiconductor devices is a semiconductor device according to one or more of the foregoing illustrative embodiments.

These and other exemplary embodiments will be described in or become apparent from the following detailed description of exemplary embodiments, which is to be read in connection with the accompanying drawings.

### BRIEF DESCRIPTION OF THE DRAWINGS

Exemplary embodiments will be described below in more detail, with reference to the accompanying drawings, of which:

FIG. 1A is a top-down view of a semiconductor structure for use at a first-intermediate fabrication stage, according to an illustrative embodiment.

FIG. 1B is a cross-sectional view of the semiconductor structure taken along the X-X axis of FIG. 1A for use at the first-intermediate fabrication stage, according to an illustrative embodiment.

FIG. 1C is a cross-sectional view of a semiconductor structure taken along the Y-Y axis of FIG. 1A for use at the first-intermediate fabrication stage, according to an illustrative embodiment.

FIG. 2A is a cross-sectional view of the semiconductor structure taken along the X-X axis of FIG. 1A for use at a second-intermediate fabrication stage, according to an illustrative embodiment.

FIG. 2B is a cross-sectional view of the semiconductor structure taken along the Y-Y axis of FIG. 1A for use at the second-intermediate fabrication stage, according to an illustrative embodiment.

FIG. 3A is a cross-sectional view of the semiconductor structure taken along the X-X axis of FIG. 1A for use at a third-intermediate fabrication stage, according to an illustrative embodiment.

FIG. 3B is a cross-sectional view of the semiconductor structure taken along the Y-Y axis of FIG. 1A for use at the third-intermediate fabrication stage, according to an illustrative embodiment.

FIG. 4A is a cross-sectional view of the semiconductor structure taken along the X-X axis of FIG. 1A for use at a fourth-intermediate fabrication stage, according to an illustrative embodiment.

FIG. 4B is a cross-sectional view of the semiconductor structure taken along the Y-Y axis of FIG. 1A for use at the fourth-intermediate fabrication stage, according to an illustrative embodiment.

FIG. 5A is a cross-sectional view of the semiconductor structure taken along the X-X axis of FIG. 1A for use at a fifth-intermediate fabrication stage, according to an illustrative embodiment.

FIG. 5B is a cross-sectional view of the semiconductor structure taken along the Y-Y axis of FIG. 1A for use at the fifth-intermediate fabrication stage, according to an illustrative embodiment.

FIG. 6A is a cross-sectional view of the semiconductor structure taken along the X-X axis of FIG. 1A for use at a sixth-intermediate fabrication stage, according to an illustrative embodiment.

FIG. 6B is a cross-sectional view of the semiconductor structure taken along the Y-Y axis of FIG. 1A for use at the sixth-intermediate fabrication stage, according to an illustrative embodiment.

FIG. 7A is a cross-sectional view of the semiconductor structure taken along the X-X axis of FIG. 1A for use at a seventh-intermediate fabrication stage, according to an illustrative embodiment.

FIG. 7B is a cross-sectional view of the semiconductor structure taken along the Y-Y axis of FIG. 1A for use at the seventh-intermediate fabrication stage, according to an illustrative embodiment.

FIG. 8A is a cross-sectional view of the semiconductor structure taken along the X-X axis of FIG. 1A for use at an eighth-intermediate fabrication stage, according to an illustrative embodiment.

FIG. 8B is a cross-sectional view of the semiconductor structure taken along the Y-Y axis of FIG. 1A for use at the eighth-intermediate fabrication stage, according to an illustrative embodiment.

FIG. 9A is a cross-sectional view of the semiconductor structure taken along the X-X axis of FIG. 1A for use at a ninth-intermediate fabrication stage, according to an illustrative embodiment.

FIG. 9B is a cross-sectional view of the semiconductor structure taken along the Y-Y axis of FIG. 1A for use at the ninth-intermediate fabrication stage, according to an illustrative embodiment.

FIG. 10A is a cross-sectional view of the semiconductor structure taken along the X-X axis of FIG. 1A for use at a tenth-intermediate fabrication stage, according to an illustrative embodiment.

FIG. 10B is a cross-sectional view of the semiconductor structure taken along the Y-Y axis of FIG. 1A for use at the tenth-intermediate fabrication stage, according to an illustrative embodiment.

FIG. 11A is a cross-sectional view of the semiconductor structure taken along the X-X axis of FIG. 1A starting from FIG. 9A for use at a first-intermediate fabrication stage, according to an alternative illustrative embodiment.

FIG. 11B is a cross-sectional view of the semiconductor structure taken along the Y-Y axis of FIG. 1A starting from FIG. 9B for use at the first-intermediate fabrication stage, according to an alternative illustrative embodiment.

FIG. 12A is a cross-sectional view of the semiconductor structure taken along the X-X axis of FIG. 1A for use at a second-intermediate fabrication stage, according to an alternative illustrative embodiment.

FIG. 12B is a cross-sectional view of the semiconductor structure taken along the Y-Y axis of FIG. 1A for use at the second-intermediate fabrication stage, according to an alternative illustrative embodiment.

### DETAILED DESCRIPTION

This disclosure relates generally to semiconductor devices, and more particularly to semiconductor structures having a wrap-around source/drain metal contact on a source/drain region and connected to a backside power distribution network, and methods for their fabrication. However, it is to be understood that embodiments of the present disclosure are not limited to the illustrative methods, apparatus, systems and devices but instead are more broadly applicable to other suitable methods, apparatus, systems and devices.

Detailed embodiments of the semiconductor structures and methods are disclosed herein. The method steps described below do not form a complete process flow for manufacturing integrated circuits, such as, semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right-side surface in the drawings.

As used herein, “width” or “length” refers to a size of an element (e.g., a layer, trench, hole, opening, etc.) in the drawings measured from a side surface to an opposite surface of the element.

As used herein, terms such as “upper”, “lower”, “right”, “left”, “vertical”, “horizontal”, “top”, “bottom”, and derivatives thereof are to be broadly construed to relate to the disclosed structures and methods, as oriented in the drawings, wherein such structures may be understood to have the same configuration (e.g., layers stacked in the same order) even if the structure is rotated to a different angle from that shown in the drawings.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms “on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

It is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description. It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present, such as 1% or less than the stated amount.

Reference in the specification to “one embodiment” or “an embodiment” of the present principles, as well as other variations thereof, means that a particular feature, structure, characteristic, and so forth described in connection with the embodiment is included in at least one embodiment of the present principles. Thus, the appearances of the phrase “in one embodiment” or “in an embodiment”, as well any other variations, appearing in various places throughout the specification are not necessarily all referring to the same embodiment. The term “positioned on” means that a first element, such as a first structure, is present on a second element, such as a second structure, wherein intervening elements, such as an interface structure, e.g., interface layer, may be present between the first element and the second element. The term “direct contact” means that a first element, such as a first structure, and a second element, such as a second structure, are connected without any intermediary conducting, insulating or semiconductor layers at the interface of the two elements.

It will be understood that, although the terms first, second, etc. may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include, but are not limited to, physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

In the IC chip fabrication industry, there are three sections referred to in a typical IC chip build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices. Accordingly, illustrative embodiments described herein may be directed to BEOL semiconductor processing and structures. BEOL is the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than 10 metal layers may be added in the BEOL. The conductive contacts of the MOL layer provide electrical connections between the integrated circuitry of the FEOL layer and a first level of metallization of a BEOL structure that is formed over the FEOL/MOL layers.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

Conventional semiconductor structures have a source/drain metal contact disposed on a top surface of a source/drain region thereby not being able to connect to a backside power distribution network. Illustrative embodiments overcome the foregoing drawback by providing a wrap-around source/drain metal contact on a source/drain region which allows for it to be connected to a backside power distribution network. This, in turn, allows for a reduction in the contact resistance since the major resistance typically comes from the source/drain metal contact to the source/drain region. In addition, there is an increase in the contact area between the source/drain metal contact and the source/drain region. Also, by utilizing a backside source/drain metal contact, the pattern density on the frontside of the semiconductor structure can be reduced.

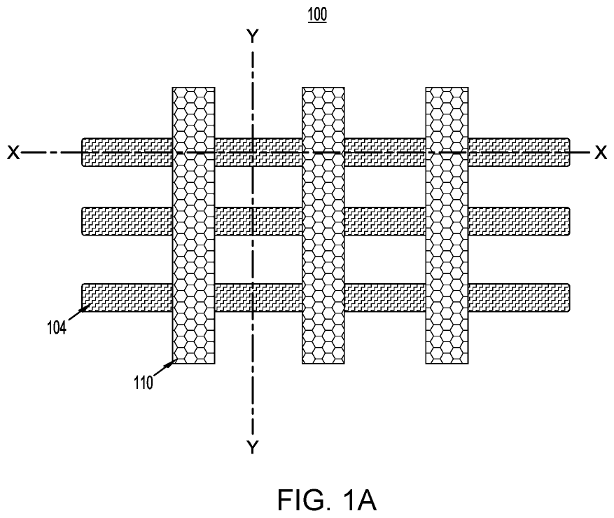

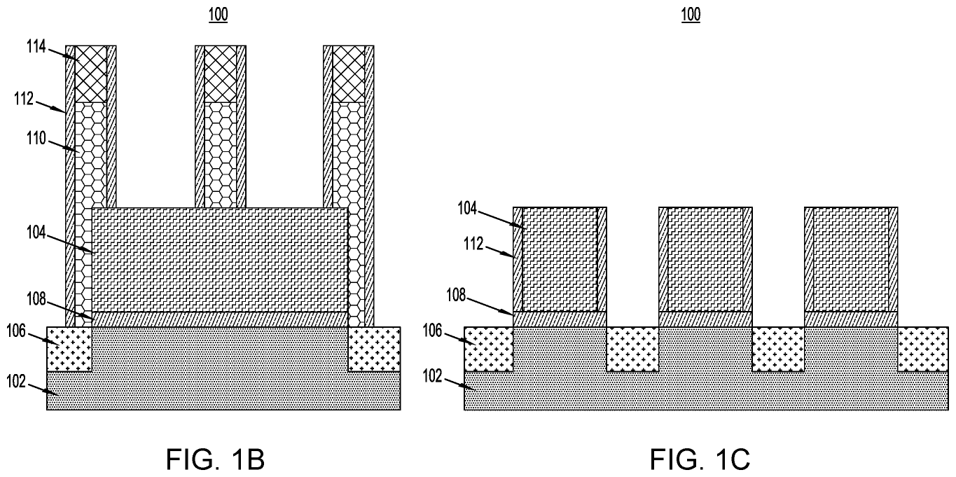

Referring now to the drawings in which like numerals represent the same or similar elements, FIGS. 1A-12B illustrate various processes for fabricating semiconductor structures with a wrap-around metal contact on a source/drain region and connected to a backside power distribution network. Note that the same reference numeral (100) is used to denote the semiconductor structure through the various intermediate fabrication stages illustrated in FIGS. 1A-12B. Note also that the semiconductor structures described herein can also be considered to be a semiconductor device and/or an integrated circuit, or some part thereof. For the purpose of clarity, some fabrication steps leading up to the production of the semiconductor structures as illustrated in FIGS. 1A-12B are omitted. In other words, one or more well-known processing steps which are not illustrated but are well-known to those of ordinary skill in the art have not been included in the figures. This is not intended to be interpreted as a limitation of any particular embodiment, or illustration, or scope of the claims.

Referring now to FIG. 1A-10B, FIG. 1A shows a top-down view of a semiconductor structure 100, FIG. 1B shows a cross-sectional view of semiconductor structure 100 and FIG. 1C shows a cross-sectional view of semiconductor structure 100. The top-down view of FIG. 1A shows semiconductor structure 100 with nanosheet channel layers 104 and dummy gates 110. The cross-sectional view of FIG. 1B is taken along the line X-X in the top-down view, and the cross-sectional view of FIG. 1C is taken along the line Y-Y in the top-down view.

Semiconductor structure 100 shows a substrate 102. Substrate 102 may be formed of any suitable semiconductor structure, including various silicon-containing materials including but not limited to silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), zinc selenide (ZnSe), etc. In one illustrative embodiment, substrate 102 is silicon.

Semiconductor structure 100 further shows nanosheet channel layers 104. Nanosheet channel layers 104 may be formed of Si or another suitable material (e.g., a material similar to that used for substrate 102).

Semiconductor structure 100 further shows STI regions 106 in substrate 102. STI regions 106 may be formed of a dielectric material such as silicon dioxide (SiO₂), silicon oxycarbide (SiOC), silicon oxynitride (SiON), etc.

Semiconductor structure 100 further includes a bottom dielectric isolation (BDI) layer 108. BDI layer 108 can be a nitride or an oxynitride such as, for example, Si₃N₄, silicon boron carbide nitride (SiBCN), SiNC, SiN, SiCO, SiO₂ and SiNOC.

Semiconductor structure 100 further includes dummy gates 110, sidewall spacers 112 and a hardmask layer 114. Suitable dummy gate material for dummy gates 110 includes, for example, polycrystalline silicon, amorphous silicon or microcrystal silicon. Sidewall spacers 112 may be formed of any suitable insulator, such as SiN, SiBCN, SiCO, SiO₂ and silicon oxycarbonitride (SiOCN). In some exemplary embodiments, sidewall spacers 112 can include a material that is resistant to some etching processes such as, for example, HF chemical etching or chemical oxide removal etching. Hardmask layer 114 can be composed of a flowable organic material such as, for example, a spin-on-carbon (SOC), Si₃N₄, SiBCN, SiNC, SiN, SiCO, SiO₂, and SiNOC.

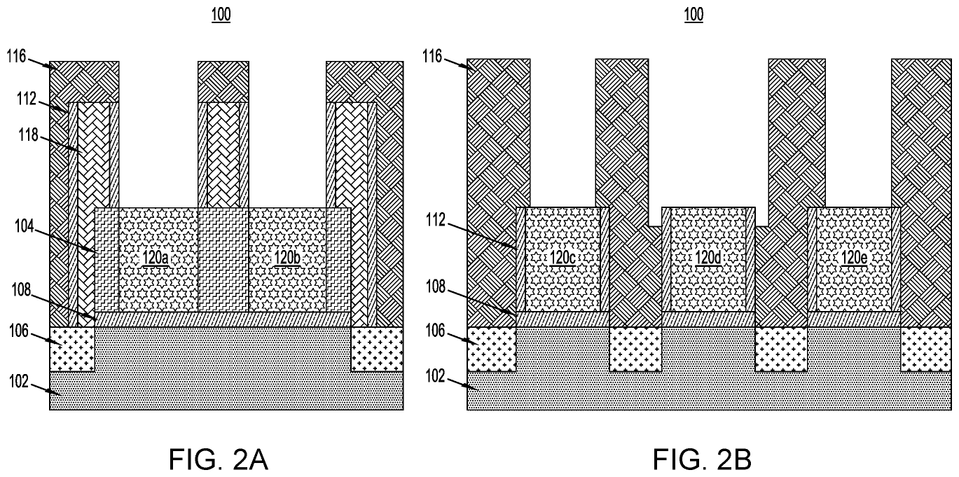

FIGS. 2A and 2B show semiconductor structure 100 at a second-intermediate fabrication stage. During this stage, nanosheet channel layers 104 are selectively etch using, for example, RIE to expose BDI layer 108, followed by formation of frontside source/drain regions 120a-120e.

Frontside source/drain regions 120a-120e may be formed using epitaxial growth processes. Frontside source/drain regions 120a-120e may be suitably doped, such as using ion implantation, gas phase doping, plasma doping, plasma immersion ion implantation, cluster doping, infusion doping, liquid phase doping, solid phase doping, etc. N-type dopants may be selected from a group of phosphorus (P), arsenic (As) and antimony (Sb), and p-type dopants may be selected from a group of boron (B), boron fluoride (BF₂), gallium (Ga), indium (In), and thallium (TI). In some embodiments, the epitaxy process includes in-situ doping (dopants are incorporated in epitaxy material during epitaxy).

Epitaxial materials may be grown from gaseous or liquid precursors. Epitaxial materials may be grown using vapor-phase epitaxy (VPE), molecular-beam epitaxy (MBE), liquid-phase epitaxy (LPE), rapid thermal chemical vapor deposition (RTCVD), metal organic chemical vapor deposition (MOCVD), ultra-high vacuum chemical vapor deposition (UHVCVD), low-pressure chemical vapor deposition (LPCVD), limited reaction processing CVD (LRPCVD), or other suitable processes. Epitaxial silicon, silicon germanium (SiGe), germanium (Ge), and/or carbon doped silicon (Si: C) silicon can be doped during deposition (in-situ doped) by adding dopants, such as n-type dopants (e.g., phosphorus or arsenic) or p-type dopants (e.g., boron or gallium), depending on the type of transistor to be formed. The dopant concentration in the source/drain can range from 1×10¹⁹ cm⁻³ to 3×10²¹ cm⁻³, or preferably between 2×10²⁰ cm⁻³ to 3×10²¹ cm⁻³. In some embodiments, frontside source/drain regions 120a-120e can be one of p-type source/drain regions and n-type source/drain regions.

Next, dummy gates 110 and hardmask layer 114 are removed using one or more wet or dry etching processes to thereby define a gate cavity where a replacement gate structure will subsequently be formed for semiconductor structure 100. Replacement gate structures 118 are then formed in the gate cavity. Replacement gate structures 118 depicted herein are intended to be representative in nature of any type of gate structure that may be employed in manufacturing integrated circuit products using so-called gate-last (replacement gate) manufacturing techniques. Replacement gate structures 118 typically include a gate dielectric layer and a gate conductor layer. The gate dielectric layer may be formed of a high-k dielectric material. Examples of high-k dielectric materials include but are not limited to metal oxides such as HfO₂, hafnium silicon oxide (Hf—Si—O), hafnium silicon oxynitride (HfSiON), lanthanum oxide (La₂O₃), lanthanum aluminum oxide (LaAlO₃), zirconium oxide (ZrO₂), zirconium silicon oxide, zirconium silicon oxynitride, tantalum oxide (Ta₂O₅), titanium oxide (TiO₂), barium strontium titanium oxide, barium titanium oxide, strontium titanium oxide, yttrium oxide (Y₂O₃), aluminum oxide (Al₂O₃), lead scandium tantalum oxide, and lead zinc niobate. The high-k dielectric material may further include dopants such as lanthanum (La), aluminum (Al), and magnesium (Mg). The gate dielectric layer may have a uniform thickness.

The gate conductor layer may include a metal gate or work function metal (WFM). The WFM for the gate conductor layer may be titanium (Ti), titanium nitride (TiN), tantalum (Ta), tantalum nitride (TaN), aluminum (Al), titanium aluminum (TiAl), titanium aluminum carbon (TiAlC), a combination of Ti and Al alloys, a stack which includes a barrier layer (e.g., of TiN, TaN, etc.) followed by one or more of the aforementioned WFM materials, etc. It should be appreciated that various other materials may be used for the gate conductor layer as desired.

An interlayer dielectric (ILD) layer 116 is formed over frontside source/drain regions 120a-120e, replacement gate structures 118 and STI regions 106 by convention techniques such as ALD, PVD, CVD, etc. ILD layer 116 may be formed of any suitable isolating material, such as SiO₂, SiOC, SiON, etc. Next, ILD layer 116 is subjected to lithographic and patterning processes to form openings to expose the top surface of frontside source/drain regions 120a, 120b, 120c and 120e, and the top surfaces of frontside source/drain regions 120d and sidewall spacers 112 using a selective etching process such as RIE.

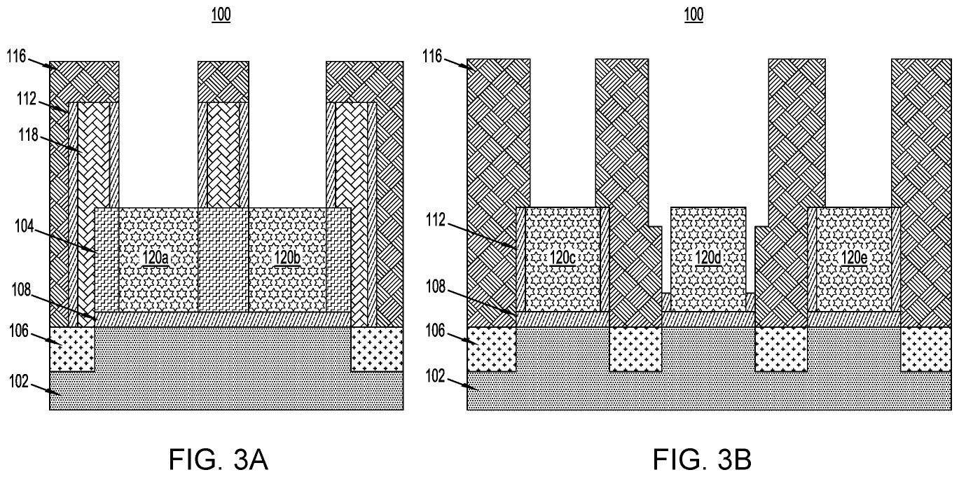

FIGS. 3A and 3B show semiconductor structure 100 at a third-intermediate fabrication stage. During this stage, a portion of the exposed sidewall spacers 112 on frontside source/drain region 120d is selectively removed using, for example, a suitable wet or dry etching process. FIG. 3B shows BDI layer 108 disposed on a bottom surface of frontside source/drain region 120d, and sidewall spacers 112 on a portion of each sidewall of frontside source/drain region 120d.

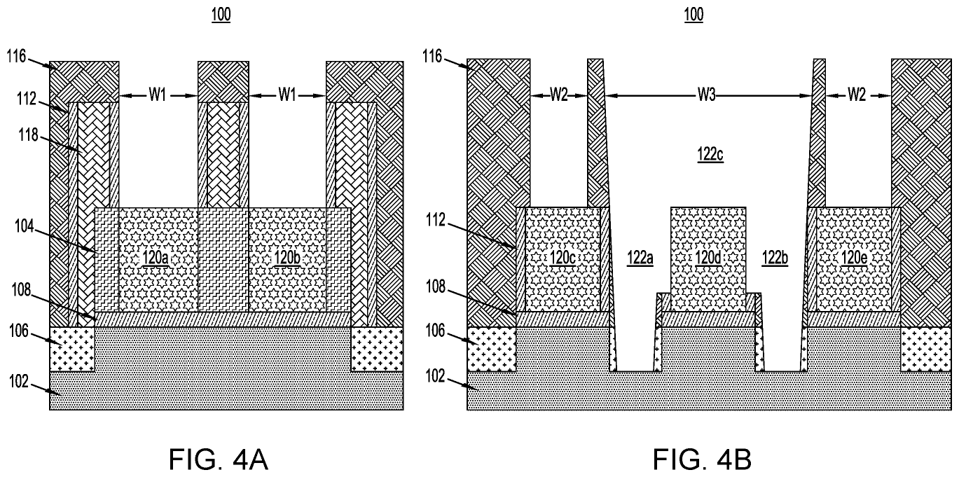

FIGS. 4A and 4B show semiconductor structure 100 at a fourth-intermediate fabrication stage. During this stage, vias 122a and 122b and trench 122c are formed by selectively removing a portion of ILD layer 116 and STI regions 106 using, for example, RIE. FIGS. 4A and 4B further show that the openings above frontside source/drain regions 120a and 120b are of a first width W1, the openings above frontside source/drain regions 120c and 120e are of a second width W2, and the openings above frontside source/drain region 120d is of a third width W3. In some embodiments, the width of width W1 and width W3 is greater than the width of width W2. In some embodiments, the width of width W1 is less than the width of width W3.

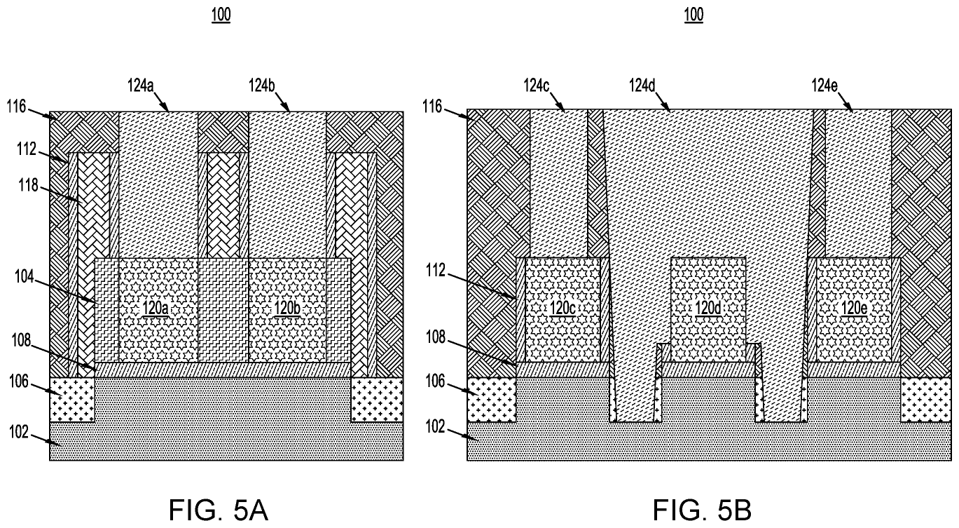

FIGS. 5A and 5B show semiconductor structure 100 at a fifth-intermediate fabrication stage. During this stage, frontside source/drain metal contacts 124a-124e are formed on frontside source/drain regions 120a-120e using any conventional technique such as ALD, CVD, PVD, and/or plating. Suitable contact metals include, a silicide liner such as Ti, Ni, or NiPt, etc., a thin adhesion metal liner, such as TiN, and high conductive metal fills, such as, for example, tungsten (W), aluminum (Al), copper (Cu), cobalt (Co), ruthenium (Ru), molybdenum (Mo), or any other suitable conductive material. The contact metals can be planarized using, for example, a planarizing process such as CMP. Other planarization processes can include grinding and polishing. As shown in FIG. 5B, by depositing the contact metal in vias 122a and 122b and trench 122c, frontside source/drain region 120d is partially disposed in frontside source/drain metal contact 124d with a bottom surface of frontside source/drain region 120d being disposed on BDI layer 108. For example, the contact metal is disposed on a top surface and portions of sidewalls of frontside source/drain region 120d. Thus, frontside source/drain metal contact 124d can also be referred to as a wrap-around frontside metal contact. For example, a frontside metal contact with a frontside source/drain region partially disposed therein can be considered a partially-wrapped frontside metal contact.

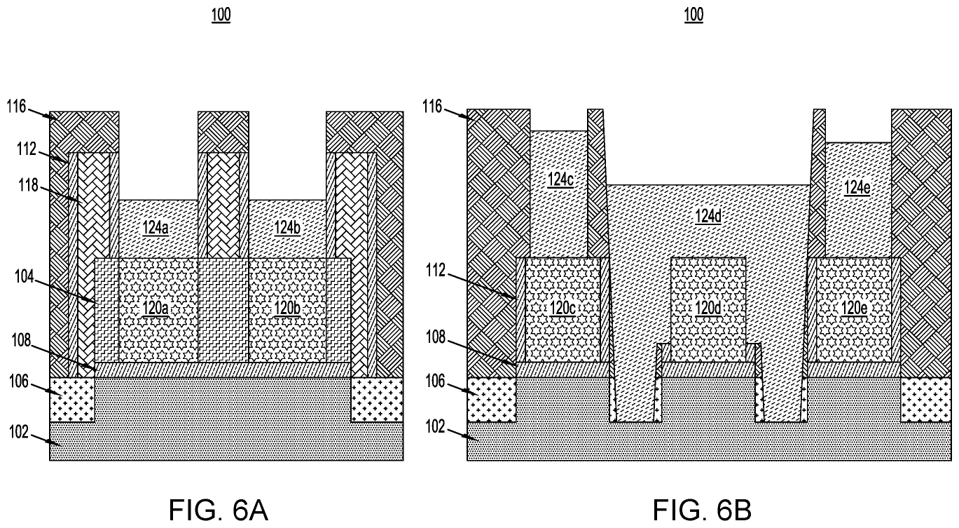

FIGS. 6A and 6B show semiconductor structure 100 at a sixth-intermediate fabrication stage. During this stage, frontside source/drain metal contacts 124a-124e are recessed using, for example, RIE or other suitable etching processes. Since frontside source/drain metal contacts 124a, 124b and 124d were formed in openings having a width greater than the width of the openings for frontside source/drain metal contacts 124c and 124e (see FIGS. 4A and 4B), the frontside source/drain metal contacts 124a, 124b and 124d will be selectively recessed at a faster rate than frontside source/drain metal contacts 124c and 124e.

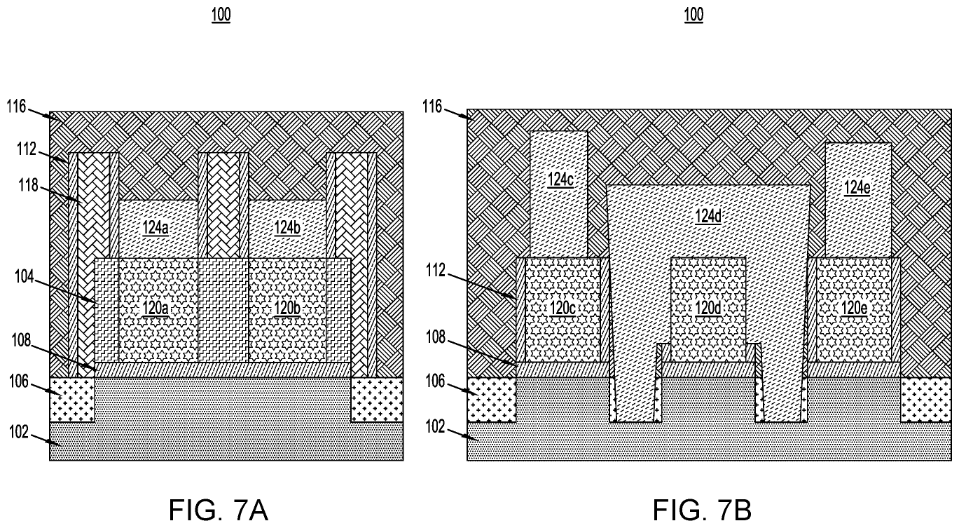

FIGS. 7A and 7B show semiconductor structure 100 at a seventh-intermediate fabrication stage. During this stage, additional ILD layer 116 is deposited on frontside source/drain metal contacts 124a-124e by convention techniques such as ALD, PVD, CVD, etc., followed by a planarization process such as CMP.

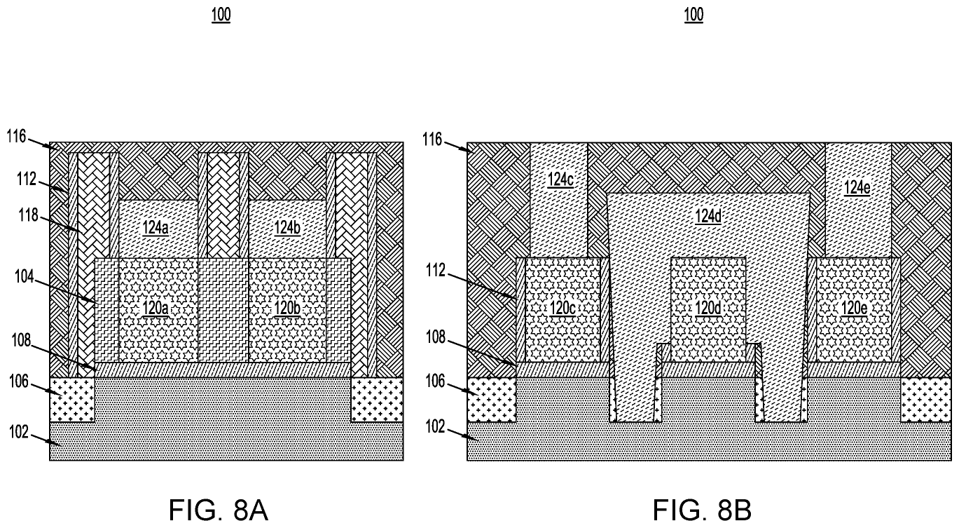

FIGS. 8A and 8B show semiconductor structure 100 at an eighth-intermediate fabrication stage. During this stage, the additional ILD layer 116 will be subjected to a further planarization process such as CMP until a top surface of frontside source/drain metal contacts 124c and 124e is reached.

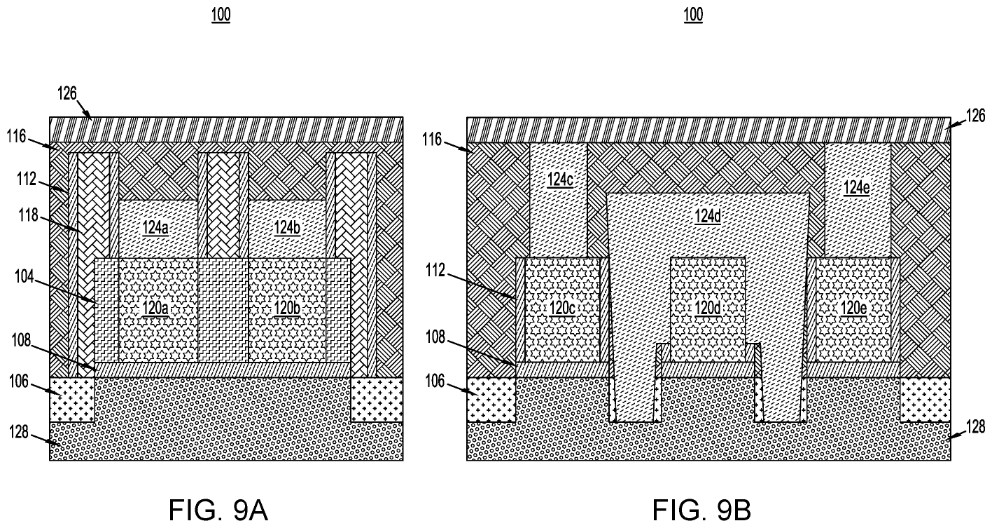

FIGS. 9A and 9B show semiconductor structure 100 at a ninth-intermediate fabrication stage. During this stage, a frontside BEOL interconnect 126 having various BEOL interconnect structures is formed. For example, frontside BEOL interconnect 126 is a metallization structure that includes one or more metal layers disposed on a side of semiconductor structure 100 opposite of the side on which the backside BEOL metallization structure is disposed. The metal layers of the frontside BEOL interconnect 126 each have metal lines for making interconnections to the semiconductor device. In particular, frontside BEOL interconnect 126 includes one or more metal layers that include metal lines for carrying power signals (e.g., a positive and/or negative voltage signal and/or ground signal) for providing power routing between the backside and the frontside of the semiconductor structure 100. Power routing involves metal lines configured to carry a power signal. For example, semiconductor structure 100 may require power to operate. In the example of FETs as semiconductor structure 100, a power signal may need to be coupled to a gate, source, and/or drain of the FET for its desired function and operation.

Next, the backside of substrate 102 is processed by, for example, flipping a carrier wafer (not shown) formed on frontside BEOL interconnect 126 over so that the backside of substrate 102 (i.e., the back surface) is facing up for backside processing. In particular, using the flipped structure, substrate 102 may be removed from the backside using, for example, a substrate grinding, a planarization (e.g., using CMP) and a wet etch to selectively remove substrate 102 until STI regions 106 and BDI layer 108 are reached.

A backside ILD layer 128 is deposited on the exposed STI regions 106 and BDI layer 108 using any conventional deposition technique such as ALD, CVD, PVD, etc., followed by a planarization process (e.g., using CMP). Backside ILD layer 128 may be formed of any suitable isolating material, such as SiO₂, SiOC, SiON, etc.

FIG. 9B further shows frontside source/drain metal contact 124d disposed on a top surface and over a portion of each sidewall of frontside source/drain region 120d, BDI layer 108 disposed on a bottom surface of frontside source/drain region 120d, and sidewall spacers 112 disposed on a remaining portion of each sidewall of frontside source/drain region 120d. In addition, frontside source/drain metal contact 124d disposed on the portion of each sidewall of the frontside source/drain region 120d is further disposed on at least one sidewall of sidewall spacers 112 and further extends into backside ILD layer 128.

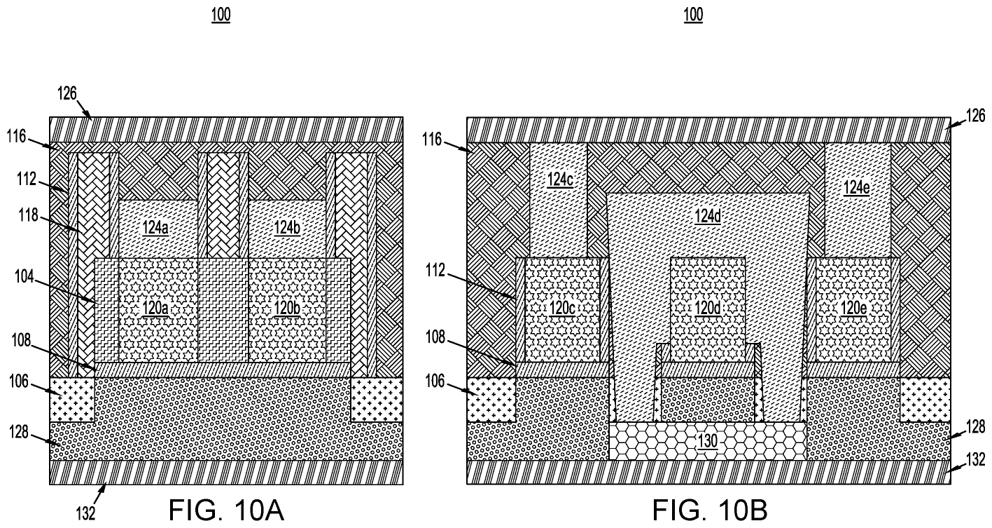

FIGS. 10A and 10B illustrate semiconductor structure 100 at a tenth-intermediate fabrication stage. During this stage, a middle-of-the-line contact 130 and a backside power delivery network 132 are formed. For example, backside ILD layer 128 is subjected to lithographic and patterning processes and then selectively etched using, for example, an isotropic etching process. An opening is formed in backside ILD layer 128 and exposing a bottom surface of frontside source/drain metal contacts 124d (not shown) formed in vias 122a and 122b (see FIG. 5B). A contact metal is then deposited in the opening to form middle-of-the-line contact 130. The contact metal can be formed of similar processes and similar material as contact metal for frontside source/drain metal contacts 124a-124e.

Next, backside power delivery network 132 is formed over semiconductor structure 100 including middle-of-the-line contact 130 and is based on creation of a wiring scheme that is disposed on both sides of the device layer (front end of line structure).

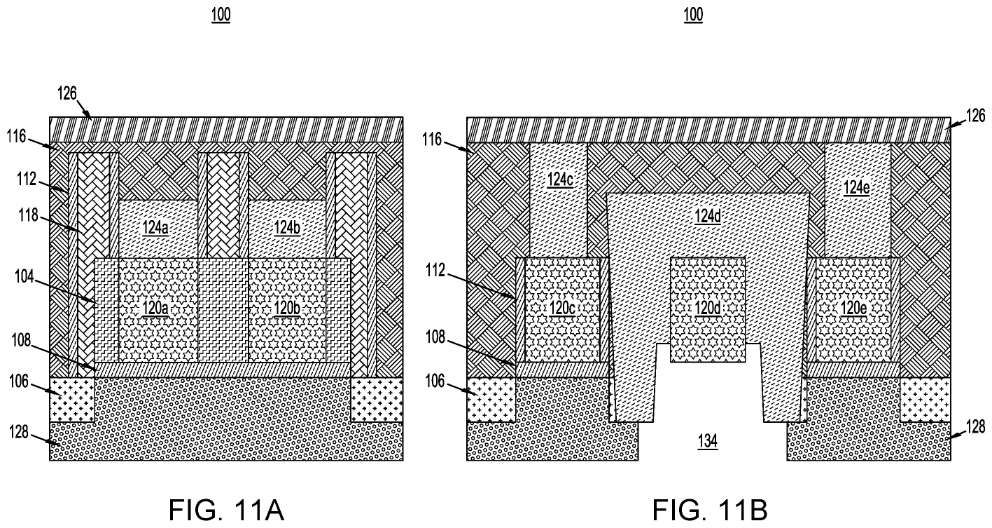

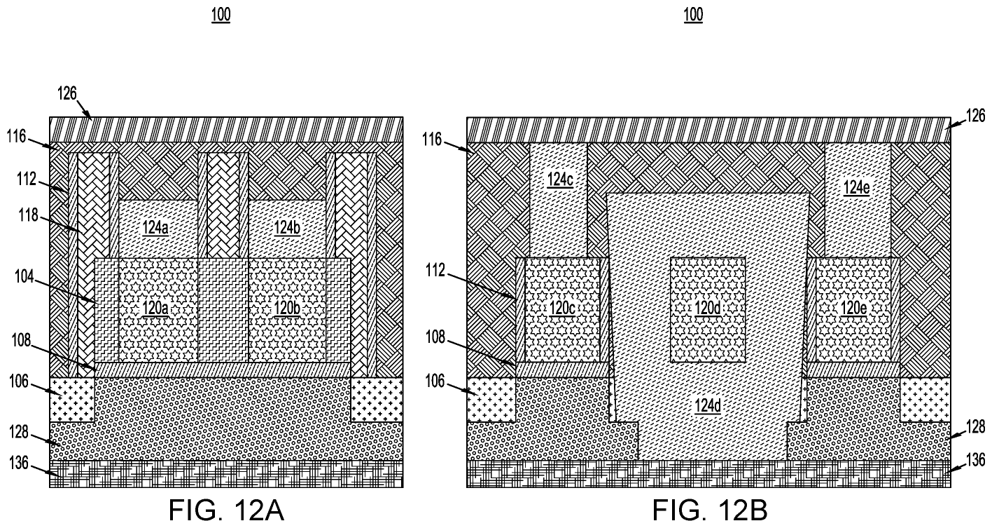

FIGS. 11A-12B illustrate an alternative embodiment of semiconductor structure 100 starting from FIGS. 9A and 9B. FIGS. 11A and 11B show semiconductor structure 100 for use at a first-intermediate fabrication stage. During this stage, backside ILD layer 128 is subjected to lithographic and patterning processes and then selectively etched using, for example, an isotropic etching process. A portion of backside ILD layer 128 is removed along with BDI layer 108 and sidewall spacers 112. An opening 134 is formed in backside ILD layer 128 and exposing a bottom portion of frontside source/drain metal contact 124d and frontside source/drain region 120d.

FIGS. 12A and 12B show semiconductor structure 100 for use at a second-intermediate fabrication stage. During this stage, a contact metal is deposited in opening 134 such that frontside source/drain metal contact 124d surrounds frontside source/drain region 120d. The contact metal can be formed of similar processes and similar material as contact metal for frontside source/drain metal contacts 124a-124e. Thus, frontside source/drain metal contact 124d can also be referred to as a wrap-around frontside metal contact. For example, a frontside metal contact with a source/drain region fully disposed therein can be considered a fully-wrapped frontside metal contact.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a first frontside source/drain region; and
a first frontside source/drain metal contact disposed on a top surface and over a portion of each sidewall of the first frontside source/drain region.

2. The semiconductor structure according to claim 1, further comprising a dielectric isolation layer disposed on a bottom surface of the first frontside source/drain region, and a sidewall spacer disposed on a remaining portion of each sidewall of the first frontside source/drain region.

3. The semiconductor structure according to claim 2, wherein the first frontside source/drain metal contact disposed on the portion of each sidewall of the first frontside source/drain region is further disposed on at least one sidewall of the sidewall spacer and further extends into a backside interlayer dielectric layer.

4. The semiconductor structure according to claim 3, further comprising a backside middle-of-the-line contact disposed in the backside interlayer dielectric layer and in contact with the first frontside source/drain metal contact.

5. The semiconductor structure according to claim 4, wherein the backside middle-of-the-line contact connects the first frontside source/drain metal contact to a backside power delivery network.

6. The semiconductor structure according to claim 1, further comprising a frontside back-end-of-the-line interconnect disposed over a top surface of the first frontside source/drain metal contact.

7. The semiconductor structure according to claim 1, further comprising a second frontside source/drain region adjacent the first frontside source/drain region.

8. The semiconductor structure according to claim 7, further comprising a second frontside source/drain metal contact disposed on the second frontside source/drain region.

9. The semiconductor structure according to claim 8, wherein the second frontside source/drain metal contact connects the second frontside source/drain region to a frontside back-end-of-the-line interconnect.

10. A semiconductor structure, comprising:
a first frontside source/drain metal contact; and
a first frontside source/drain region fully disposed within the first frontside source/drain metal contact.

11. The semiconductor structure according to claim 10, wherein a bottom surface of the first frontside source/drain metal contact is connected to a backside power delivery network.

12. The semiconductor structure according to claim 11, further comprising a frontside back-end-of-the-line interconnect disposed over a top surface of the first frontside source/drain metal contact.

13. The semiconductor structure according to claim 10, further comprising a second frontside source/drain region adjacent the first frontside source/drain region.

14. The semiconductor structure according to claim 13, further comprising a second frontside source/drain metal contact disposed on the second frontside source/drain region.

15. The semiconductor structure according to claim 14, wherein the second frontside source/drain metal contact connects the second frontside source/drain region to a frontside back-end-of-the-line interconnect.

16. An integrated circuit, comprising:
one or more semiconductor structures, wherein at least one of the one or more semiconductor structures comprises:
a frontside source/drain region; and
a frontside source/drain metal contact disposed on a top surface and over a portion of each sidewall of the frontside source/drain region.

17. The integrated circuit according to claim 16, wherein the frontside source/drain metal contact is further disposed on a bottom surface and over a remaining portion of each sidewall of the frontside source/drain region.

18. The integrated circuit according to claim 16, wherein the at least one semiconductor structure further comprises a dielectric isolation layer disposed on a bottom surface of the frontside source/drain region, and a sidewall spacer disposed on a remaining portion of each sidewall of the frontside source/drain region.

19. The integrated circuit according to claim 18, wherein the frontside source/drain metal contact disposed on the portion of each sidewall of the frontside source/drain region is further disposed on at least one sidewall of the sidewall spacer and further extends into a backside interlayer dielectric layer.

20. The integrated circuit according to claim 19, wherein the at least one semiconductor structure further comprises a backside middle-of-the-line contact disposed in the backside interlayer dielectric layer and in contact with the frontside source/drain metal contact, wherein the backside middle-of-the-line contact connects the frontside source/drain metal contact to a backside power delivery network.
